(19) United States
(12) Patent Application Publication
(10) Pub. No.: US 2026/0149413 A1
(43) Pub. Date: May 28, 2026

(54) DIFFERENTIAL POWER AMPLIFIER

(71) Applicant: Murata Manufacturing Co., Ltd., Nagaokakyo-shi (JP)

(72) Inventor: Yuito SAWAYAMA, Nagaokakyo-shi (JP)

(21) Appl. No.: 19/387,968

(22) Filed: Nov. 13, 2025

(30) Foreign Application Priority Data
Nov. 22, 2024 (JP) 2024-203905

(51) Int. Cl. H03F 1/08; H03F 3/24; H03F 3/45

(52) U.S. Cl. CPC H03F 1/08; H03F 3/24; H03F 3/45475; H03F 2200/09; H03F 2200/451; H03F 2200/541; H03F 2203/7233

(57) ABSTRACT

A differential power amplifier includes: a plurality of differential amplifiers; a first balun transformer that converts a balanced output signal of a first differential amplifier into an unbalanced signal; a second balun transformer that converts a balanced output signal of a second differential amplifier into an unbalanced signal; and a switch circuit that directly connects, in a first mode, an unbalanced output terminal of the first balun transformer and an unbalanced output terminal of the second balun transformer, and connects, in a second mode, the unbalanced output terminal of the first balun transformer and the unbalanced output terminal of the second balun transformer with a capacitor interposed in between. In the first mode, both the first differential amplifier and the second differential amplifier perform an amplification operation. In the second mode, the first differential amplifier performs an amplification operation, and the second differential amplifier does not perform an amplification operation.

### CROSS REFERENCE TO RELATED APPLICATION

This application claims priority from Japanese Patent Application No. 2024-203905, filed on Nov. 22, 2024. The content of this application is incorporated herein by reference in its entirety.

### BACKGROUND OF THE DISCLOSURE

### 1. Field of the Disclosure

The present disclosure relates to a differential power amplifier.

### 2. Description of the Related Art

In the field of mobile communications such as cellular phones, a power amplifier circuit obtained by combining a plurality of differential amplifiers is disclosed. Japanese Unexamined Patent Application Publication No. 2010-141673 describes that a wide-band frequency characteristic is realized by combining the outputs of a plurality of differential amplifiers.

### BRIEF SUMMARY OF THE DISCLOSURE

Japanese Unexamined Patent Application Publication No. 2010-141673 does not describe a configuration that attenuates harmonic components in differential amplification. Further, when a plurality of differential amplifiers are used to realize, for example, EN-DC (E-UTRAN New Radio-Dual Connectivity), it is necessary to optimize the bandpass characteristics for each band.

The present disclosure has been made in view of the above problems, and a possible benefit of the present disclosure is to, in a configuration in which a plurality of differential amplifiers are used, realize a differential power amplifier which can optimize the bandpass characteristics of each band.

A differential power amplifier according to an aspect of the present disclosure includes: a plurality of differential amplifiers; a first balun transformer that converts a balanced output signal of a first differential amplifier into an unbalanced signal; a second balun transformer that converts a balanced output signal of a second differential amplifier into an unbalanced signal; and a switch circuit that directly connects, in a first mode, an unbalanced output terminal of the first balun transformer and an unbalanced output terminal of the second balun transformer, and connects, in a second mode, the unbalanced output terminal of the first balun transformer and the unbalanced output terminal of the second balun transformer with a capacitor interposed in between. In the first mode, both the first differential amplifier and the second differential amplifier perform an amplification operation. In the second mode, the first differential amplifier performs an amplification operation, and the second differential amplifier does not perform an amplification operation.

According to the present disclosure, it is possible to realize a differential power amplifier that can optimize, in a configuration in which a plurality of differential amplifiers are used, the bandpass characteristics for each band.

### BRIEF DESCRIPTION OF THE SEVERAL VIEWS OF THE DRAWINGS

FIG. 1A is a first diagram showing a configuration example of a differential power amplifier according to Embodiment 1;

FIG. 1B is a second diagram showing the configuration example of the differential power amplifier according to Embodiment 1;

FIG. 2 is a graph showing an example of a simulation result of frequency-gain characteristics in a second mode of the differential power amplifier according to Embodiment 1;

FIG. 3A is a first diagram showing a configuration example of a differential power amplifier according to Embodiment 2;

FIG. 3B is a second diagram showing the configuration example of the differential power amplifier according to Embodiment 2;

FIG. 4 is a graph showing an example of a simulation result of frequency-gain characteristics in a second mode of the differential power amplifier according to Embodiment 2;

FIG. 5A is a first diagram showing a configuration example of a differential power amplifier according to a modification of Embodiment 2; and

FIG. 5B is a second diagram showing the configuration example of the differential power amplifier according to the modification of Embodiment 2.

### DETAILED DESCRIPTION OF THE DISCLOSURE

Hereinafter, differential power amplifiers according to embodiments will be described in detail with reference to the accompanying drawings. It should be noted that the present disclosure is not limited by such embodiments. Also, the components of each embodiment include those that can be easily replaced by a person skilled in the art or those that are substantially the same. Each embodiment is an example, and partial replacement or combination of the configurations shown in different embodiments is possible. In Embodiment 2 and subsequent embodiments, descriptions of matters common to Embodiment 1 will be omitted, and only point(s) different from Embodiment 1 will be described. In particular, identical or similar effects of identical or similar configurations will not be described one by one for each embodiment.

### Embodiment 1

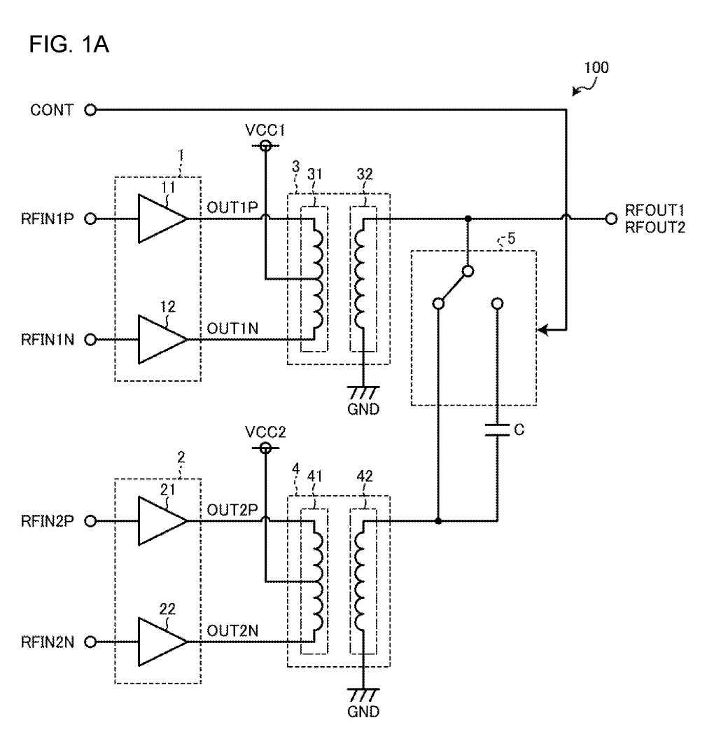

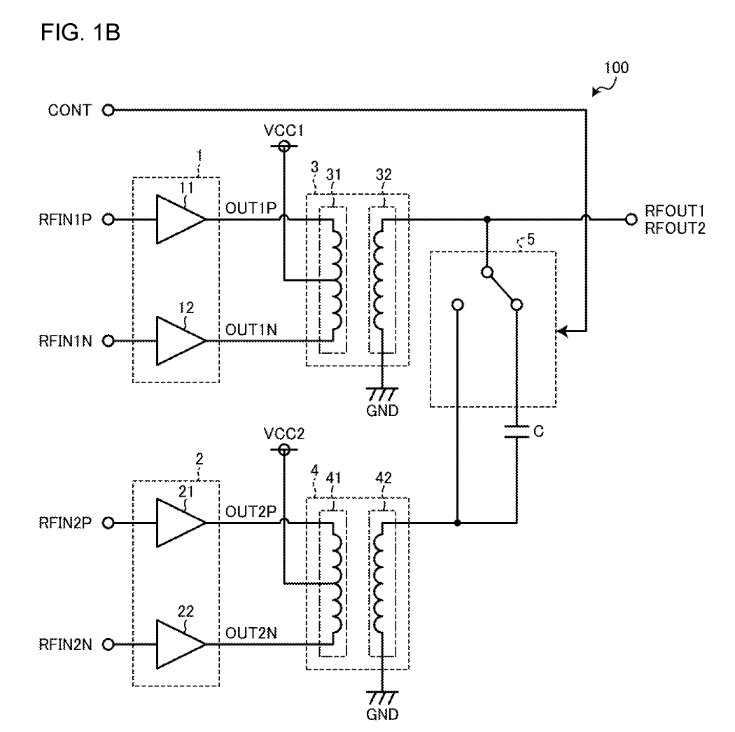

FIG. 1A is a first diagram showing a configuration example of a differential power amplifier according to Embodiment 1. FIG. 1B is a second diagram showing the configuration example of the differential power amplifier according to Embodiment 1. As shown in FIGS. 1A and 1B, a differential power amplifier 100 according to Embodiment 1 includes a first differential amplifier 1, a second differential amplifier 2, a first balun transformer 3, a second balun transformer 4, and a switch circuit 5.

In the present disclosure, the band of a first differential signal inputted to the first differential amplifier 1 and the band of a second differential signal inputted to the second differential amplifier 2 are the same. The differential power amplifier 100 according to Embodiment 1 has a first mode in which both the first differential amplifier 1 and the second differential amplifier 2 perform an amplification operation, and a second mode in which the first differential amplifier 1 performs an amplification operation and the second differential amplifier 2 does not perform an amplification operation. FIG. 1A shows a state in which the differential power amplifier 100 is in the first mode, and FIG. 1B shows a state in which the differential power amplifier 100 is in the second mode.

In the present disclosure, the input signal in the first mode is, for example, a signal in a frequency band defined by 2G (Second Generation Mobile Communication System). In the present disclosure, the input signal in the second mode is, for example, a signal in a frequency band defined by 5G (Fifth Generation Mobile Communication System). The input signal in the second mode is not limited to 5G, but may alternatively be a signal in a frequency band defined by 4G (Fourth Generation Mobile Communication System) or a signal in a frequency band defined 6G (Sixth Generation Mobile Communication System).

The example shown in FIGS. 1A and 1B exemplifies an aspect in which both an output signal RFOUT1 in the first mode and an output signal RFOUT2 in the second mode are outputted from the same node as the unbalanced output terminal of the first balun transformer 3, but the present disclosure is not limited to such an aspect. For example, the present disclosure also includes an aspect in which the output signal RFOUT1 in the first mode is outputted from the same node as the unbalanced output terminal of the second balun transformer 4.

The first differential amplifier 1 includes two amplifiers 11 and 12 for amplifying the first differential signal. The amplifier 11 amplifies an input signal RFIN1P. The amplifier 12 amplifies an input signal RFIN1N.

The second differential amplifier 2 includes two amplifiers 21 and 22 for amplifying the second differential signal. The amplifier 21 amplifies an input signal RFIN2P. The amplifier 22 amplifies an input signal RFIN2N.

The amplifiers 11, 12, 21, and 22 may each be constituted by, for example, a bipolar transistor, or be constituted by, for example, an FET. When the amplifiers 11, 12, 21, and 22 are each constituted by a bipolar transistor, for example, an HBT is exemplified. The present disclosure is not limited by the constitution of the amplifiers 11, 12, 21, and 22.

The first balun transformer 3 includes an input-side winding wire 31 and an output-side winding wire 32.

The input-side winding wire 31 is connected between an output OUT1P and an output OUT1N of the first differential amplifier 1. A center tap is provided at the midpoint of the input-side winding wire 31, and a power supply voltage VCC1 is applied to the center tap.

The input-side winding wire 31 and the output-side winding wire 32 of the first balun transformer 3 are electromagnetically coupled. Thus, the balanced output signal outputted from the first differential amplifier 1 is balanced/unbalanced and converted by the first balun transformer 3.

The second balun transformer 4 includes an input-side winding wire 41 and an output-side winding wire 42.

The input-side winding wire 41 is connected between an output OUT2P and an output OUT2N of the second differential amplifier 2. A center tap is provided at the midpoint of the input-side winding wire 41, and a power supply voltage VCC2 is applied to the center tap.

The input-side winding wire 41 and the output-side winding wire 42 of the second balun transformer 4 are electromagnetically coupled. Thus, the balanced output signal outputted from the second differential amplifier 2 is balanced/unbalanced and converted by the second balun transformer 4.

In the example shown in FIGS. 1A and 1B, the switch circuit 5 is, for example, a multiplexer having a 2-to-1 connection. Note that the configuration of the switch circuit 5 shown in FIGS. 1A and 1B is an example, and the present disclosure is not limited by the configuration of the switch circuit 5.

In the differential power amplifier 100 according to Embodiment 1, in the first mode, as shown in FIG. 1A, the switch circuit 5 directly connects the unbalanced output terminal of the first balun transformer 3 and the unbalanced output terminal of the second balun transformer 4. Thus, the output power of the first differential amplifier 1 and the output power of the second differential amplifier 2 are combined, so that relatively large power can be outputted.

Further, in the second mode, as shown in FIG. 1B, the switch circuit 5 connects the unbalanced output terminal of the first balun transformer 3 and the unbalanced output terminal of the second balun transformer 4 with a capacitor C interposed in between. Thus, an LC series resonance circuit obtained using the output-side winding wire 42 of the second balun transformer 4 is configured.

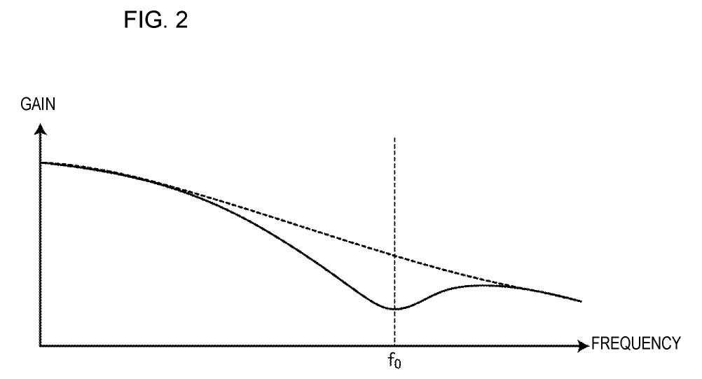

FIG. 2 is a graph showing an example of a simulation result of frequency-gain characteristics in the second mode of the differential power amplifier according to Embodiment 1. In the example shown in FIG. 2, the broken line indicates a simulation result of frequency-gain characteristics in the second mode when the capacitor C is not provided. In the second mode, by connecting the unbalanced output terminal of the first balun transformer 3 and the unbalanced output terminal of the second balun transformer 4 with the capacitor C interposed in between, an LC series resonance circuit having a predetermined frequency as a resonant frequency f₀ is configured, as shown by the solid line in FIG. 2.

In the configuration of the differential power amplifier 100 according to Embodiment 1, harmonic components can be effectively attenuated by appropriately setting the capacitance value of the capacitor C in accordance with the band of the first differential signal inputted to the first differential amplifier 1. Thus, the bandpass characteristics of the first differential signal can be optimized.

In addition, it is possible to contribute to the miniaturization of the differential power amplifier by using the output-side winding wire 42 of the second balun transformer 4 as the inductor of the LC series resonance circuit.

### Embodiment 2

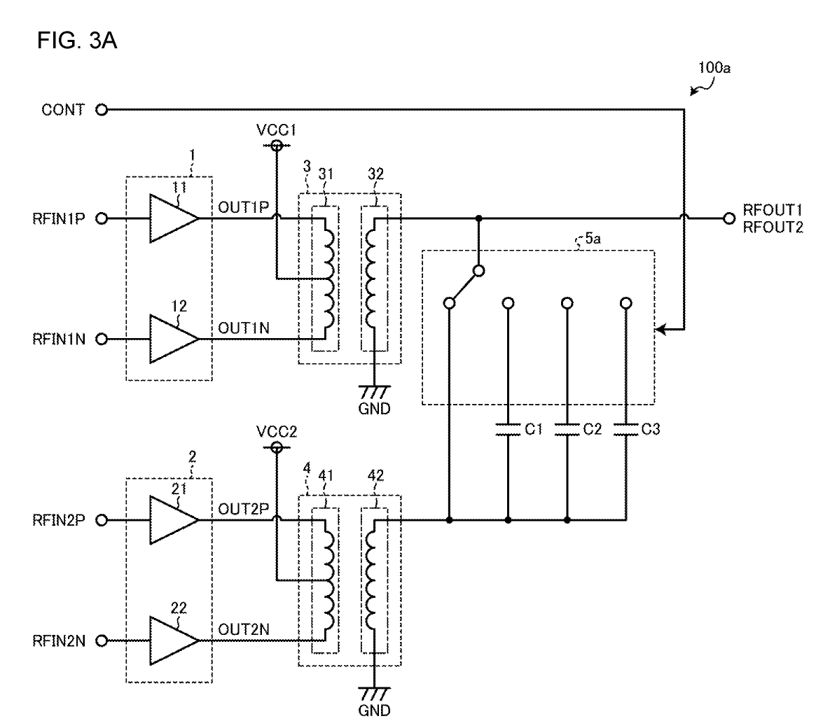

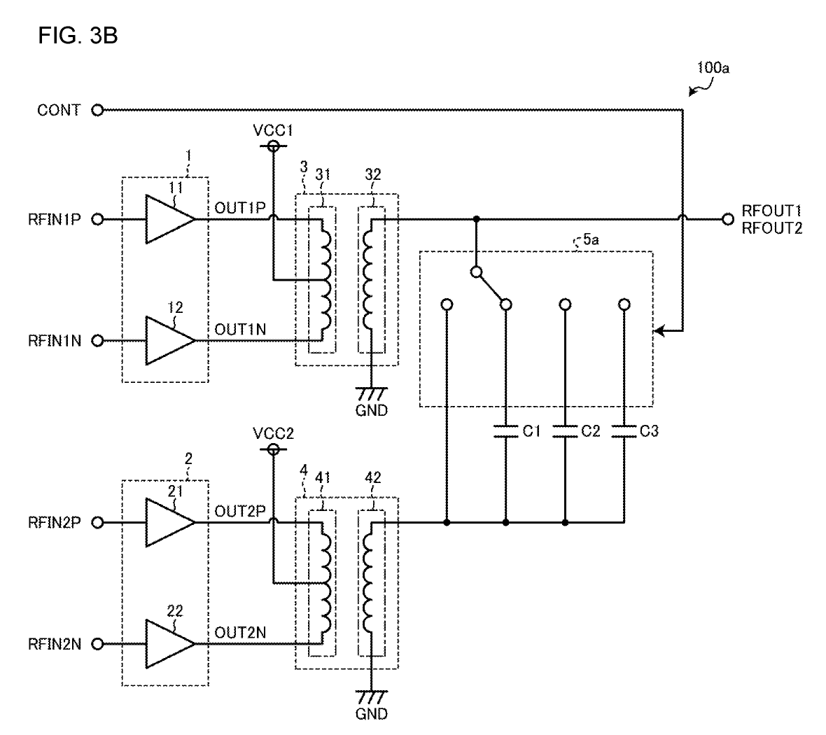

FIG. 3A is a first diagram showing a configuration example of a differential power amplifier according to Embodiment 2. FIG. 3B is a second diagram showing the configuration example of the differential power amplifier according to Embodiment 2.

In the example shown in FIGS. 3A and 3B, the capacitance values of capacitors C1, C2, and C3 are different from each other. Further, in the example shown in FIGS. 3A and 3B, a switch circuit 5a is, for example, a multiplexer having an n-to-1 connection (here n = 4). Note that the configuration of the switch circuit 5a shown in FIGS. 3A and 3B is only an example, and the present disclosure is not limited by the configuration of the switch circuit 5a.

In a differential power amplifier 100a according to Embodiment 2, in the first mode, as shown in FIG. 3A, the switch circuit 5a directly connects the unbalanced output terminal of the first balun transformer 3 and the unbalanced output terminal of the second balun transformer 4. Thus, the output power of the first differential amplifier 1 and the output power of the second differential amplifier 2 are combined, so that relatively large power can be outputted.

Further, in the second mode, as shown in FIG. 3B, the switch circuit 5a switches the capacitance of the capacitor connected between the unbalanced output terminal of the first balun transformer 3 and the unbalanced output terminal of the second balun transformer 4. In the example shown in FIG. 3B, an aspect is exemplified in which the capacitor C1 is connected between the unbalanced output terminal of the first balun transformer 3 and the unbalanced output terminal of the second balun transformer 4.

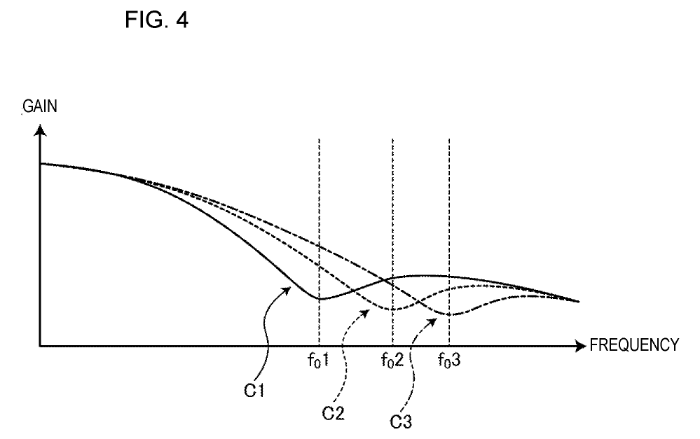

FIG. 4 is a graph showing an example of a simulation result of frequency-gain characteristics in the second mode of the differential power amplifier according to Embodiment 2. Each line in FIG. 4 shows a simulation result of frequency-gain characteristics in the second mode when each of the capacitors C1, C2, and C3 is provided. In the example shown in FIG. 4, the magnitude relationship of the capacitance values of the capacitors C1, C2, and C3 is C1 > C2 > C3. In such a case, the magnitude relationship of resonant frequencies f₀1, f₀2, and f₀3 is f₀1 < f₀2 < f₀3.

In the configuration of the differential power amplifier 100a according to Embodiment 2, it is possible to effectively attenuate harmonic components having different frequencies for each band by selecting a capacitor having a capacitance value corresponding to the band of the first differential signal inputted to the first differential amplifier 1. Thus, it is possible to optimize the bandpass characteristics of the first differential signal for each band.

### Modification

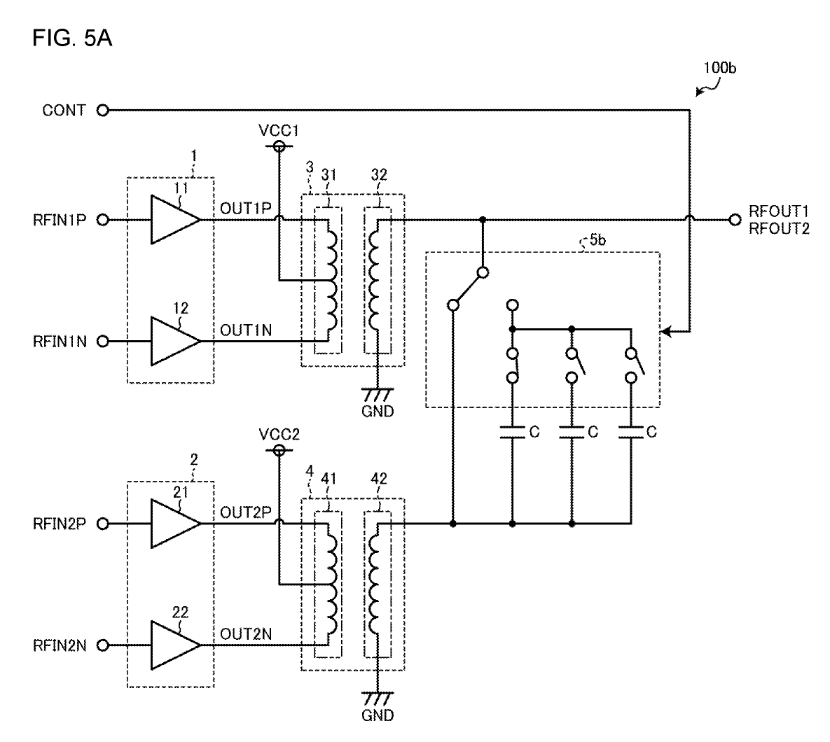

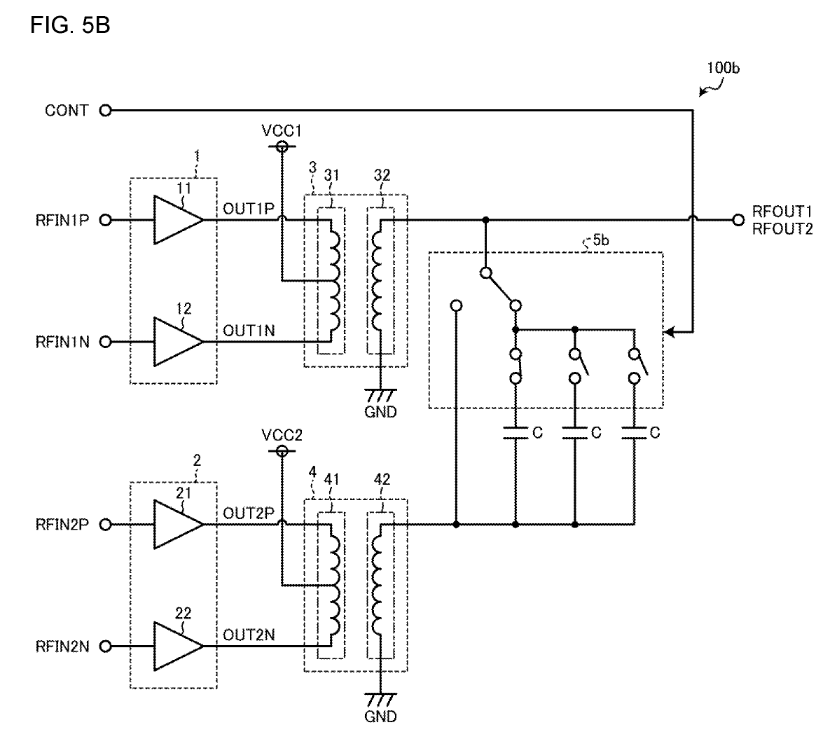

FIG. 5A is a first diagram showing a configuration example of a differential power amplifier according to a modification of Embodiment 2. FIG. 5B is a second diagram showing the configuration example of the differential power amplifier according to the modification of Embodiment 2.

In the example shown in FIGS. 5A and 5B, the capacitance values of three capacitors C may be the same as or different from each other. Note that the configuration of a switch circuit 5b shown in FIGS. 5A and 5B is only an example, and the present disclosure is not limited by the configuration of the switch circuit 5b.

In a differential power amplifier 100b according to the modification of Embodiment 2, in the first mode, as shown in FIG. 5A, the switch circuit 5b directly connects the unbalanced output terminal of the first balun transformer 3 and the unbalanced output terminal of the second balun transformer 4. Thus, the output power of the first differential amplifier 1 and the output power of the second differential amplifier 2 are combined, so that relatively large power can be outputted.

Further, in the second mode, as shown in FIG. 5B, the switch circuit 5b changes the number of capacitors connected between the unbalanced output terminal of the first balun transformer 3 and the unbalanced output terminal of the second balun transformer 4. In the example shown in FIG. 5B, an aspect is exemplified in which one capacitor C is connected between the unbalanced output terminal of the first balun transformer 3 and the unbalanced output terminal of the second balun transformer 4.

In the configuration of the differential power amplifier 100b according to the modification of Embodiment 2, the capacitance value corresponding to the band of the first differential signal inputted to the first differential amplifier 1 can be set by changing the number of capacitors connected between the unbalanced output terminal of the first balun transformer 3 and the unbalanced output terminal of the second balun transformer 4. Thus, as in the differential power amplifier 100a according to Embodiment 2, the bandpass characteristics of the first differential signal for each band can be optimized.

It should be noted that the embodiments described above are intended to facilitate understanding of the present disclosure, and are not intended to limit the interpretation of the present disclosure. The present disclosure may be changed/modified without departing from its scope, and the present disclosure also includes equivalents thereof.

What is claimed is:

1. A differential power amplifier comprising:
a plurality of differential amplifiers, comprising a first differential amplifier and a second differential amplifier;
a first balun transformer configured to convert a balanced output signal of the first differential amplifier into a first unbalanced signal;
a second balun transformer configured to convert a balanced output signal of the second differential amplifier into a second unbalanced signal; and
a switch circuit that is configured to:
in a first mode, directly connect an unbalanced output terminal of the first balun transformer and an unbalanced output terminal of the second balun transformer, and
in a second mode, connect the unbalanced output terminal of the first balun transformer and the unbalanced output terminal of the second balun transformer with a capacitor interposed in between,
wherein in the first mode, both the first differential amplifier and the second differential amplifier are configured to perform an amplification operation, and
wherein in the second mode, the first differential amplifier is configured to perform an amplification operation, and the second differential amplifier is configured to not perform an amplification operation.

2. The differential power amplifier according to claim 1, wherein, in the second mode, the switch circuit is configured to switch a capacitance of the capacitor.

3. The differential power amplifier according to claim 1, wherein, in the second mode, the switch circuit is configured to change a number of capacitors connected between the unbalanced output terminal of the first balun transformer and the unbalanced output terminal of the second balun transformer.

4. The differential power amplifier according to claim 2, wherein, in the second mode, the switch circuit is configured to change a number of capacitors connected between the unbalanced output terminal of the first balun transformer and the unbalanced output terminal of the second balun transformer.
